(19) United States
(12) Patent Application Publication
(10) Pub. No.: US 2005/0054126 A1
(43) Pub. Date: Mar. 10, 2005

(54) System and method for marking the surface of a semiconductor package

(75) Inventor: Akira Matsunami, Beppu City (JP)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/651,771

(22) Filed: Aug. 29, 2003

(51) Int. Cl. H01L 21/66

(52) U.S. Cl. 438/15

(57) ABSTRACT

In one embodiment, a method for marking a surface of a semiconductor package comprises determining a highest element position within the semiconductor package and determining an excluded surface portion of a surface of the semiconductor package corresponding to the highest element position. The method further comprises determining a printing pattern for marking the surface of the semiconductor package with one or more marks, the printing pattern excluding the excluded surface portion of the surface of the semiconductor package. The method further comprises marking the surface of the semiconductor package with the one or more marks according to the determined printing pattern.

### TECHNICAL FIELD OF THE INVENTION

This invention relates generally to semiconductor packages and more particularly to a system and method for marking the surface of a semiconductor package.

### BACKGROUND

Semiconductor packages such as integrated circuit packages generally include one or more wire bonds connecting a first component of the semiconductor package to one or more second components of the semiconductor package. A package body generally surrounds the wire bonds and the first and second components such that a distance exists between a surface of the package body and a highest wire loop position or other component of the semiconductor package. It is often desirable to mark a surface of the semiconductor package, on a surface of the package body for example. A danger may exist that marking the surface of the package body may damage one or more wire loops or other components of the semiconductor package, at the highest wire loop position for example. As the size of semiconductor packages decreases, this danger may increase because the distance between the surface of the semiconductor package and the highest wire loop position may decrease. The laser marking may also damage the structural integrity of the package body if the marking of the surface reduces the distance between the surface of the package body and the highest wire loop position by an undesirable amount.

### SUMMARY OF THE INVENTION

According to the present invention, certain disadvantages and problems associated with previous techniques for marking a surface of a semiconductor package may be reduced or eliminated.

In one embodiment, a method for marking a surface of a semiconductor package comprises determining a highest element position within the semiconductor package and determining an excluded surface portion of a surface of the semiconductor package corresponding to the highest element position. The method further comprises determining a printing pattern for marking the surface of the semiconductor package with one or more marks, the printing pattern excluding the excluded surface portion of the surface of the semiconductor package. The method further comprises marking the surface of the semiconductor package with the one or more marks according to the determined printing pattern.

In another embodiment, a system for marking a surface of a semiconductor package comprises a memory operable to store a highest element position within the semiconductor package. The system also comprises one or more processors collectively operable to: (1) determine the highest element position within the semiconductor package; (2) determine an excluded surface portion of a surface of the semiconductor package corresponding to the highest element position; and (3) determine a printing pattern for marking the surface of the semiconductor package with the one or more marks, the printing pattern excluding the excluded surface portion of the surface of the semiconductor package. The system also comprises marking equipment operable to mark the surface of the semiconductor package with the one or more marks according to the determined printing pattern.

Particular embodiments of the present invention may provide one or more technical advantages. In certain embodiments, marking the surface of the semiconductor package according to a printing pattern that excludes an excluded surface portion of the surface of the semiconductor package may reduce or eliminate damage to wire loops or other components of the semiconductor package caused by marking the surface. In certain embodiments, marking the surface of the semiconductor package according to the present invention may allow semiconductor package thickness to be reduced without substantially reducing the reliability or strength of the semiconductor package. In certain embodiments, the present invention may reduce or eliminate reductions in the strength of the mold compound package body or other package body of the semiconductor package resulting from marking the surface of the semiconductor package.

Certain embodiments of the present invention may provide some, all, or none of the above technical advantages. Certain embodiments may provide one or more other technical advantages, one or more of which may be readily apparent to those skilled in the art from the figures, descriptions, and claims included herein.

### BRIEF DESCRIPTION OF THE DRAWINGS

For a more complete understanding of the present invention and features and advantages thereof, reference is now made to the following description, taken in conjunction with the accompanying drawings, in which:

FIG. 1 illustrates an example system for marking a surface of a semiconductor package;

FIG. 2 illustrates a cross-sectional view of an example ball grid array (BGA) semiconductor package, which has been marked with one or more marks according to the present invention;

FIGS. 3A-3B illustrate a top view of an example process for marking a surface of a semiconductor package with one or more marks;

FIG. 4 illustrates an example method for marking a surface of a semiconductor package with one or more marks; and

FIG. 5 illustrates an example method for determining highest wire loop position within a semiconductor package using a predetermined threshold distance.

### DESCRIPTION OF EXAMPLE EMBODIMENTS

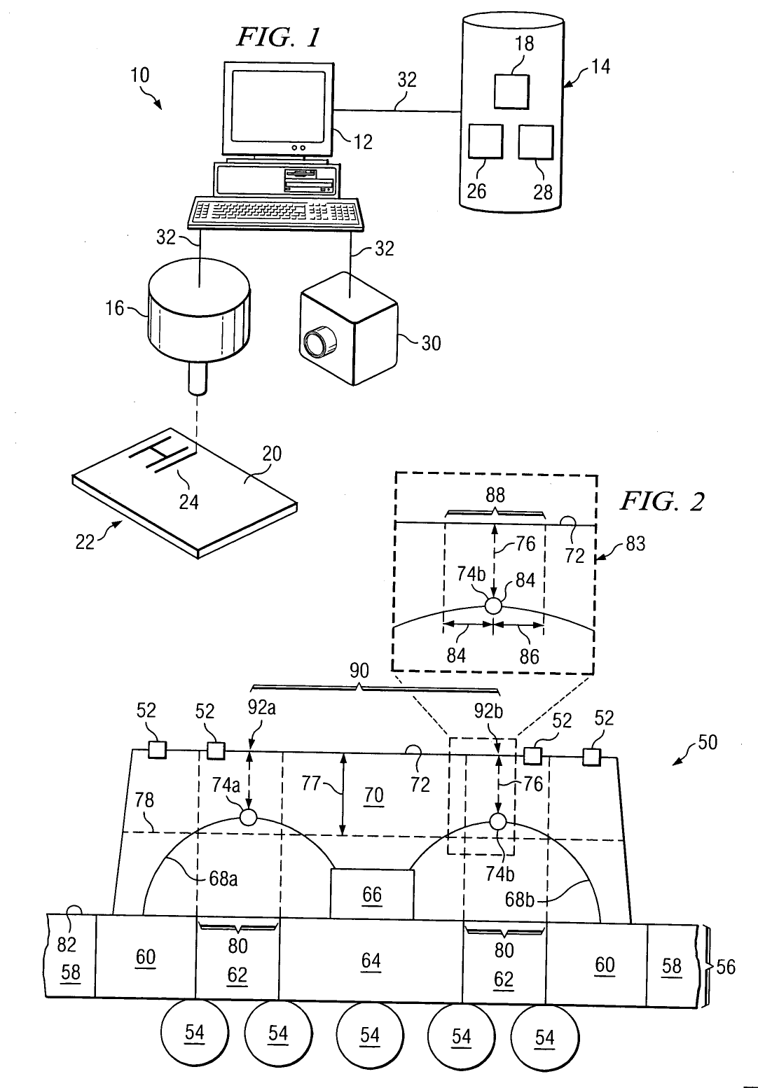

FIG. 1 illustrates an example system 10 for marking a surface of a semiconductor package. System 10 may include a computer system 12, a memory 14, and marking equipment 16. In general, computer system 12 is operable to determine a printing pattern 18 for marking a surface 20 of a semiconductor package 22, and marking equipment 16 is operable to mark surface 20 of semiconductor package 22 with one or more marks 24 according to the determined printing pattern 18. Printing pattern 18 may exclude an excluded surface portion of surface 20 of semiconductor package 22, the excluded surface portion corresponding to one or more highest element positions within semiconductor package 22. This description focuses on an embodiment in which the element comprises a wire loop of the semiconductor package and the highest element position comprises a highest wire loop position. However, the present invention contemplates the element being any suitable component of a semiconductor package and the highest element position being the highest element position of that component.

Semiconductor package 22 may include a ball grid array (BGA) type circuit, a leaded package, a printed circuit board package, or any other suitable semiconductor package, according to particular needs. Although one semiconductor package 22 is shown, the present invention contemplates system 10 marking surfaces 20 of multiple semiconductor packages 22 according to substantially similar or different printing patterns 18 as appropriate. In one embodiment, surface 20 of semiconductor package 22 comprises a surface of a mold compound package body of semiconductor package 22. However, the present invention contemplates surface 20 of semiconductor package 22 comprising any suitable material and components according to particular needs. Semiconductor package 22 may include one or more gold or other wire loops operable to provide electrical conductivity, for example, between one or more elements of semiconductor package 22.

Memory 14 may be operable to store mark information 26 for the one or more marks 24 to be marked on surface 20 of semiconductor package 22. Mark information 26 may comprise outline information, font information, size information, shape information, or any other suitable information for the one or more marks 24 to be printed on surface 20 of semiconductor structure 22. In one embodiment, the one or more marks 24 comprise a logo of the manufacturer of semiconductor package 22, an identification number of semiconductor package 22, a type number identifying the type of semiconductor package 22, or any other suitable marks 24 according to particular needs. As an example, in an embodiment in which a mark 24 comprises a logo, mark information 26 may comprise shape information and size information for the logo.

Memory 14 may be operable to store a highest wire loop position 28 for one or more wire loops within semiconductor package 22. For purposes of this description, highest wire loop position 28 may generally comprise information identifying a portion of a wire loop within semiconductor package 22 that is closer to surface 20 of semiconductor package 22 than other portions of the wire loop. Highest wire loop position 28 may also include information identifying a portion of a wire loop within semiconductor package 22 that is closer to surface 20 of semiconductor package 22 than a predetermined threshold distance. Highest wire loop position 28 may also comprise information identifying a portion of one wire loop within a semiconductor package 22 that includes multiple wire loops that is closer to surface 20 than a portion of any other wire loop within semiconductor 22. In certain embodiments, one highest wire loop position 28 may be determined and multiple wire loops may have a portion that is substantially the same distance from surface 20 as highest wire loop position 28. Highest wire loop position 28 may be determined manually or may be determined by computer system 12 as discussed below.

Computer system 12 may include one or more processors that are collectively operable to determine a highest wire loop position 28 within semiconductor package 22. In one embodiment, whether highest wire loop position 28 is determined manually or using computer system 12, highest wire loop position 28 may be determined by identifying a critical area formed between a first element and one or more second elements of the semiconductor package, and determining a highest wire loop position 28 in the critical area. The critical area may include an area in which highest wire loop position 28 is most likely to be found, for example. In one embodiment, semiconductor package 22 comprises an integrated circuit package 22. In this embodiment, the first element may include a die pad and the one or more second elements may each include inner leads of the integrated circuit package 22. Although one method of determining highest wire loop position 28 is described, the present invention contemplates determining highest wire loop position 28 in any suitable manner, according to particular needs.

Computer system 12 may be operable to determine an excluded surface portion of surface 20 of semiconductor package 22 corresponding to highest wire loop position 28. In one embodiment, computer system 12 determines a first margin from highest wire loop position 28, determines a second margin from highest wire loop position 28, and determines the excluded surface portion according to the determined first margin and the determined second margin. An example excluded surface portion of surface 20 will be described in more detail below with reference to FIG. 2.

Computer system 12 may be operable to determine a printing pattern 18 for marking surface 20 of semiconductor package 22 taking into account highest wire loop position 28. In particular, printing pattern 18 excludes the excluded surface portion of surface 20 of semiconductor package 22. In one embodiment, computer system 12 is operable to configure marking equipment 16 to mark surface 20 of semiconductor package 22 according to the determined printing pattern 18.

Computer system 12 and memory 14 may include one or more computers at one or more locations and may share data storage, communications, or other resources according to particular needs. For example, functionality described in connection with computer system 12 and memory 14 may be provided using a single computer system, which in a particular embodiment might include a conventional desktop or laptop computer. Computer system 12 may include one or more suitable input devices, output devices, mass storage media, processors, memory, or other components for receiving, processing, storing, and communicating information according to the operation of system 10. Memory 14 may include any memory or database module and may take the form of volatile or non-volatile memory including, without limitation, magnetic media, optical media, random access memory (RAM), read-only memory (ROM), removable media, or any other suitable local or remote memory component.

Marking equipment 16 may be operable to mark surface 20 of semiconductor package 22 with one or more marks 24 according to the determined printing pattern 18. In one embodiment, marking equipment 16 comprises laser marking equipment 16, although the present invention contemplates marking equipment 16 comprising any suitable type of marking equipment, according to particular needs. In certain embodiments, marking equipment 16 includes a larger irradiation area for marking surface 20 of semiconductor package 22 according to printing pattern 18 than standard marking equipment.

In one embodiment, system 10 comprises a visual inspection machine 30. Visual inspection machine 30 may be operable to facilitate inspection of surface 20 of semiconductor package 22. For example, visual inspection machine 30 may be used to inspect the one or more marks 24 on surface 20 of semiconductor package 22 for correctness, quality, adherence to printing pattern 18, compliance with marking information 26, or for any other suitable reason according to particular needs. Marking equipment 16 and visual inspection machine 30 may be one machine, multiple machines embodied as one unit, or separate units, according to particular needs.

In one embodiment, visual inspection machine 30 is operable to inspect surface 20 of semiconductor package 22 after marking equipment 16 has marked surface 20 of semiconductor package 22 with the one or more marks 24 according to printing pattern 18. In another embodiment, visual inspection machine 30 is operable to inspect surface 20 of semiconductor package 22 while marking equipment 16 is marking surface 20 of semiconductor package 22. If, using visual inspection machine 30, the marking of surface 20 of semiconductor package 22 is determined to be undesirable or incorrect, it may, in certain embodiments, be possible to modify the marking of surface 20 of semiconductor package 22. For example, it may be possible to adjust, either automatically or manually, marking equipment 16. As another example, it may be possible to adjust, either automatically or manually, printing pattern 18. Computer system 12 may be operable to configure visual inspection machine 30 to inspect surface 20 of semiconductor package 22 according to the determined printing pattern 18.

Computer system 12 and memory 14 may be associated with a single computer or a network according to particular needs. Computer system 12, memory 14, marking equipment 16, and visual inspection machine 30 may be coupled using one or more links 32. Links 32 may include direct connections, one or more local area networks (LANs), metropolitan area networks (MANs), wide area networks (WANs), a global computer network such as the Internet, or any other wireline, optical, wireless, or other links. In one embodiment, computer system 12, memory 14, and marking equipment 16 comprise a single machine.

Particular embodiments of the present invention may provide one or more technical advantages. In certain embodiments, marking surface 20 of semiconductor package 22 according to a printing pattern 18 that excludes an excluded surface portion of surface 20 of semiconductor package 22 may reduce or eliminate damage to wire loops or other components of semiconductor package 22 caused by marking surface 20. In certain embodiments, marking surface 20 of semiconductor package 22 according to the present invention may allow the thickness of semiconductor package 22 to be reduced without substantially reducing the reliability or strength of semiconductor package 22. In certain embodiments, the present invention may reduce or eliminate reductions in the strength of the mold compound package body or other package body of semiconductor package 22 resulting from marking surface 20 of semiconductor package 22.

FIG. 2 illustrates a cross-sectional view of an example ball grid array (BGA) semiconductor package 50, which has been marked with one or more marks 52 according to the present invention. In general, BGA semiconductor package 50 and marks 52 correspond to semiconductor package 22 and marks 24, respectively, as illustrated in FIG. 1. Although the illustrated semiconductor package is a BGA semiconductor package 50, this is for example purposes only, and the present invention contemplates semiconductor package 50 being any suitable type of semiconductor package. Semiconductor package 50 includes one or more conductive balls 54 (e.g., solder balls) coupled to a substrate layer 56. Solder balls 54 may be used to couple semiconductor package 50 to a printed circuit board or other suitable structure, for example. Substrate layer 56 may comprise outer leads 58, inner leads 60, dielectric regions 62, die pad 64, or any other suitable components according to particular needs.

Semiconductor package 50 may include a die 66 coupled to die pad 64. One or more wire loops 68 may couple die 66 to inner leads 60 to provide electrical conductivity within semiconductor package 50, for example. Although the illustrated cross-sectional view of semiconductor package 50 only shows two wire loops 68a and 68b, the present invention contemplates semiconductor package 50 including any suitable number of wire loops 68 facing any suitable direction within semiconductor package 50. For example, semiconductor package 50 may extend into and out of the page and may include a series of wire loops 68 that are substantially parallel to the illustrated wire loops 68 (i.e., one or more wire loops 68 substantially parallel to wire loop 68a and one or more wire loops 68 substantially parallel to wire loop 68b). Furthermore, semiconductor package 50 may be four-sided, for example, and may include one or more wire loops 68 on each of the four sides. In one embodiment, all wire loops 68 within semiconductor package 50 are substantially similar in shape, although the present invention contemplates any degree of similarity or dissimilarity among wire loops 68. Semiconductor package 50 may also include a mold compound package body 70 or other suitable package body 70 substantially covering one or more components of semiconductor package 50. Package body 70 may include a surface 72, which forms surface 72 of semiconductor package 50. In general, surface 72 of semiconductor package 50 corresponds to surface 20 of semiconductor package 22 illustrated in FIG. 1.

Semiconductor package 50 may include highest wire loop position 74, which may be separated from surface 72 by a distance 76. In general, highest wire loop position 74 corresponds to highest wire loop position 28 stored in memory 14 as illustrated in FIG. 1. Distance 76 may be any suitable distance, according to particular needs. In certain embodiments, it may be desirable for distance 76 to be at least approximately 100 μm. Highest wire loop position 74 may generally comprise a portion of a wire loop 68 within semiconductor package 50 that is closer to surface 72 of semiconductor package 50 than other portions of the wire loop 68. Highest wire loop position 74 may also comprise a portion of one wire loop 68 within a semiconductor package 50 that includes multiple wire loops 68 that is closer to surface 72 than a portion of any other wire loop 68 within semiconductor 50. In certain embodiments, one highest wire loop position 74 may be determined and multiple wire loops 68 within semiconductor package 50 may have a portion that is substantially the same distance from surface 72 as the determined highest wire loop position 74. For example, in an embodiment in which all or substantially all wire loops 68 within semiconductor package 50 have substantially the same shape, multiple wire loops may have highest wire loop positions 74 that are substantially the same. In one embodiment, a threshold distance 77 may be predetermined, forming an imaginary threshold line 78. For example, predetermined threshold distance 77 may be substantially the same as or slightly greater than an expected or known marking depth of marking equipment 16 into surface 72 of semiconductor package 50. In this embodiment, portions of wire loops 68 that are closer to surface 72 than predetermined threshold distance 77 (i.e., that are above threshold line 78) may be determined to be highest wire loop positions 74. Highest wire loop position 74 may be determined manually or may be determined by computer system 12.

Semiconductor package 50 may include a critical area 80 formed between die pad 64 and each inner lead 60. Critical area 80 describes an area of semiconductor package 50 extending upward from a surface 82 of substrate layer 56 towards surface 72 of semiconductor package 50. Critical areas 80 may each have any suitable size and shape, according to particular needs. Although critical area 80 is described as being “between” die pad 64 and each inner lead 60, the present invention contemplates critical area 80 including portions of die pad 64 and each inner lead 60. In certain embodiments, highest wire loop position 74 may exist in critical area 80. For example, in certain embodiments, it is more likely that highest wire loop position 74 is in critical area 80 than outside critical area 80. Thus, whether determining highest wire loop position 74 manually or automatically, determining highest wire loop position 74 may include identifying critical area 80 formed between die pad 64 and each inner lead 60 and determining highest wire loop position 74 in critical area 80.

An excluded surface portion 88 of surface 70 of semiconductor package 50 may be determined, by computer system 12 for example. Excluded surface portion 88 may correspond to highest wire loop position 74. For example, excluded surface portion 88 may substantially overlie highest wire loop position 74. Excluded surface portion 88 may be any suitable size, according to particular needs. As illustrated in exploded view 83, in one embodiment, using computer system 12 or manually, a first margin 84 and a second margin 86 from highest wire loop position 74 may be determined. First margin 84 and second margin 86 may be any suitable distances according to particular needs. In one embodiment, excluded surface portion 88 may be formed to include the determined first margin 84 and second margin 86. First margin 84 and second margin 86 may help ensure that the marking of surface 72 does not contact and possibly damage wire loops 68.

In one embodiment, excluded surface portion 88 may span a distance 90 across surface 72 from a first surface point 92a corresponding to highest wire loop position 74a to a second surface point 92b corresponding to an opposing highest wire loop position 74b. Although points 92 are illustrated as being directly vertical above their respective corresponding highest wire loop positions 74, the present invention contemplates points 92 being at any suitable angle from their respective corresponding wire loop positions 74 and may also take into account particular margins 84 and 86.

A printing pattern 18 for marking surface 70 of semiconductor package 50 with one or more marks 52 may be determined. Printing pattern 18 may exclude excluded surface portion 88 of surface 72 of semiconductor package 50. Surface 72 may be marked with marks 52 according to determined printing pattern 18. Thus, marks 52 may not be substantially over highest wire loop position 72, within excluded surface portion 88, for example.

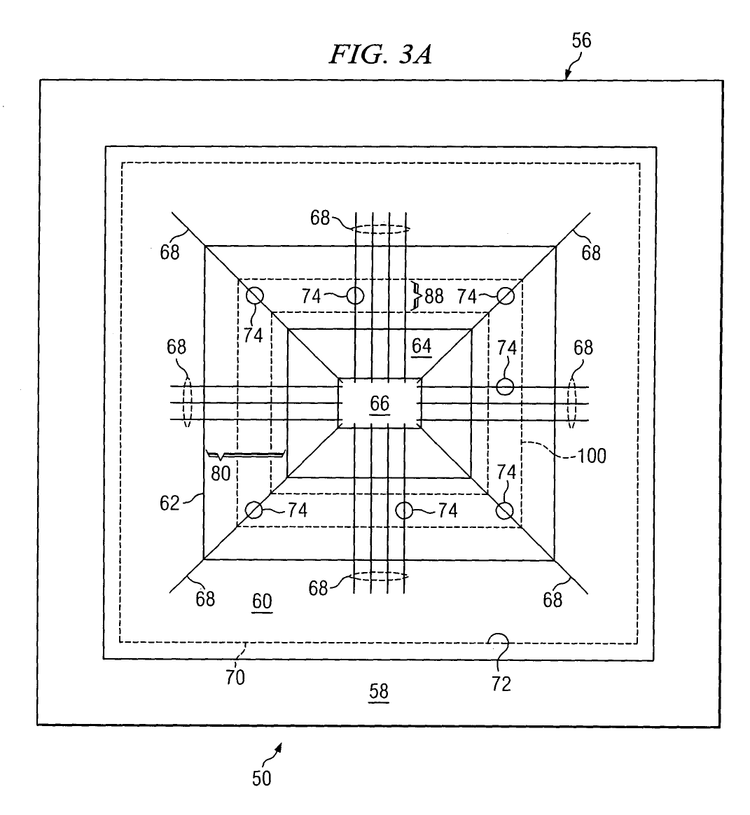

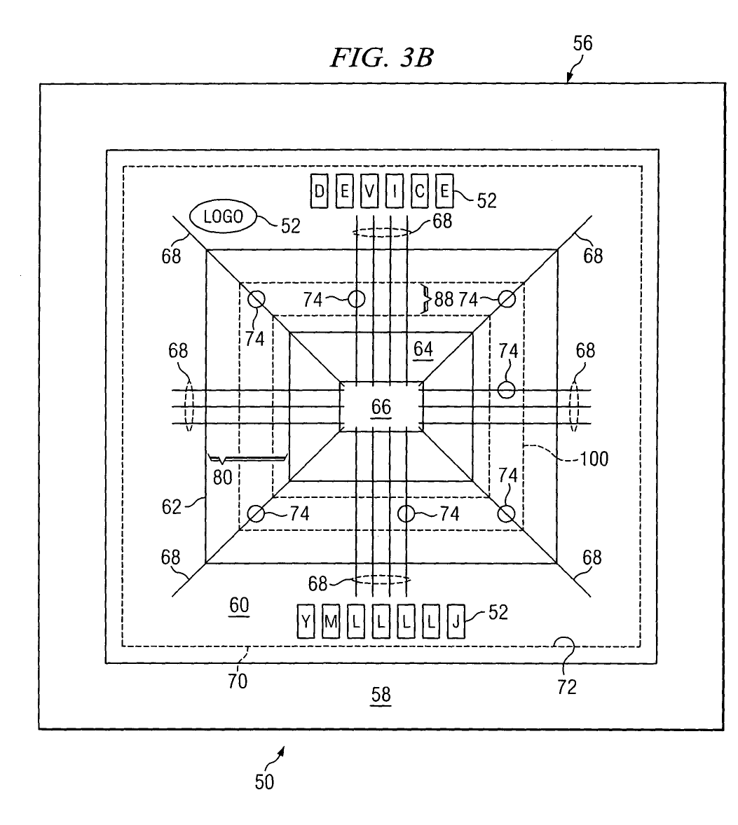

FIGS. 3A-3B illustrate a top view of an example process for marking a surface 20 of semiconductor package 22 with one or more marks 24. In particular, FIGS. 3A-3B illustrate an example process for marking surface 72 of BGA semiconductor package 50. As illustrated in FIG. 3A, semiconductor package 50 may include substrate layer 56. Substrate layer 56 may comprise outer leads 58, inner leads 60, dielectric regions 62, die pad 64, or any other suitable components according to particular needs. Package body 70 is illustrated by dotted lines to reflect that in this illustrated embodiment, certain components within semiconductor 50 are being seen through package body 70 to facilitate description of the present invention. Package body 70 may include surface 72, which forms surface 72 of semiconductor package 50.

As described above, a first margin 84 and a second margin 86 from each highest wire loop position 74 may be determined. First margin 82 and second margin 84 may be any suitable distances according to particular needs. In one embodiment, excluded surface portion 88 may be determined according to the determined first margin 82 and second margin 84. Thus, excluded surface portion 88 may form a band 100 on surface 72 of semiconductor package 50, for example. In one embodiment, the width of band 100 is the sum of the widths of first margin 84 and second margin 86. First margin 84 and second margin 86 may help ensure that the marking of surface 72 does not contact and possibly damage wire loops 68.

In one embodiment, excluded surface portion 88 may form an irregular shape on surface 72 of semiconductor package 50. For example, although the illustrated band 100 forms a substantially perfect rectangle on surface 72, the sides of band 100 may be nonlinear in certain embodiments such that excluded surface portion 88 is irregular. It may be possible to determine a margin on surface 72 from excluded surface portion 88 in the direction of the edges of surface 72. It may be desirable for the margin to be sufficient to allow formation of an extended excluded surface portion 88 having a regular shape.

A printing pattern 18 for marking surface 72 of semiconductor package 50 with one or more marks 52 may be determined. Printing pattern 18 may exclude excluded surface portion 88 of surface 72 of semiconductor package 50. As illustrated in FIG. 3B, surface 72 may be marked with marks 52 according to determined printing pattern 18. Thus, marks 52 may not be substantially over highest wire loop positions 74, within excluded surface portion 88, for example.

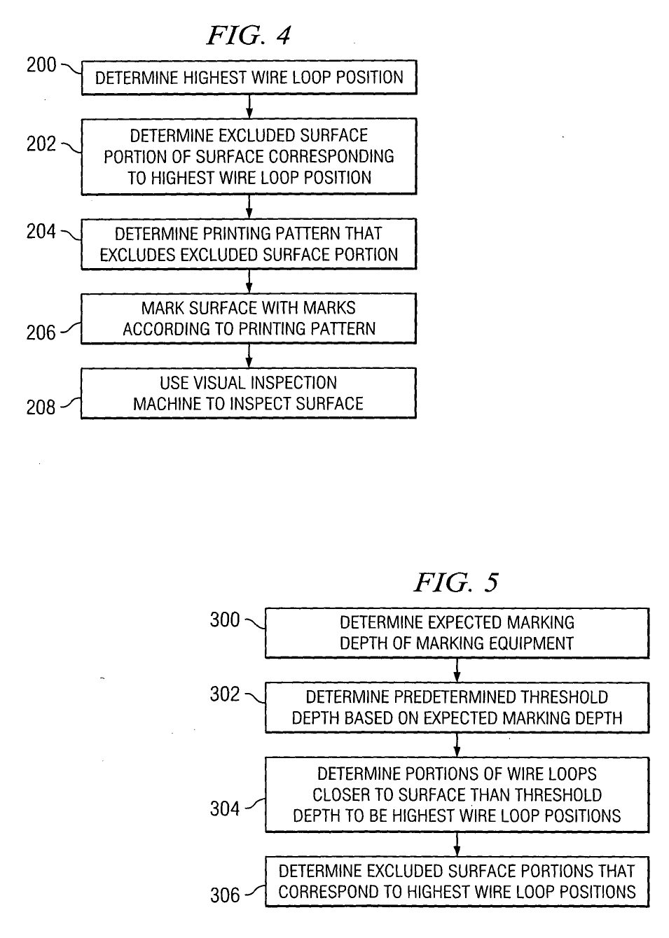

FIG. 4 illustrates an example method for marking a surface 72 of a semiconductor package 50 with one or more marks 52. Although the described method focuses on an example embodiment for marking surface 72 of semiconductor package 50, the present invention contemplates marking surface 20 of any suitable semiconductor package 22. Furthermore, although the described method focuses on an embodiment in which the highest element position comprises a highest wire loop position 74, the present invention contemplates highest element position being the highest element position of any suitable component of semiconductor package 50.

At step 200, one or more highest wire loop positions 74 are determined. In one embodiment, determining a highest wire loop position 74 includes identifying a critical area 80 formed between a die pad 64 and one or more inner leads 60 of semiconductor package 50, and determining a highest wire loop position 74 in critical area 80. In another embodiment, a threshold distance 77 may be predetermined, forming an imaginary threshold line 78. In this embodiment, portions of wire loops 68 within semiconductor package 50 that are closer to surface 72 of semiconductor package 50 than predetermined threshold distance 77 (i.e., that are above threshold line 78) may be determined to be highest wire loop positions 74. A method for determining highest wire loop position 74 according to this embodiment is illustrated below with reference to FIG. 5.

At step 202, an excluded surface portion 88 of surface 72 of semiconductor package 50 corresponding to highest wire loop position 74 is determined. In one embodiment, first margin 84 from highest wire loop position 74 and second margin 86 from highest wire loop position 74 are determined. In this embodiment, excluded surface portion 88 may be determined according to the determined first and second margins 84 and 86. For example, excluded surface portion 88 may form a band 100 on surface 72 of semiconductor package 50. At step 204, a printing pattern 18 for marking surface 72 of semiconductor package 50 with one or more marks 52 is determined based on highest wire loop position 74. Printing pattern 18 may exclude excluded surface portion 88 of surface 72 of semiconductor package 50. At step 206, surface 72 of semiconductor package 50 may be marked with the one or more marks 52 according to determined printing pattern 18. In one embodiment, marking surface 72 of semiconductor package 50 with the one or more marks 52 according to determined printing pattern 18 comprises configuring marking equipment 16 used for marking surface 72 of semiconductor package 50 with the one or more marks 52 according to determined printing pattern 18. In one embodiment, surface 72 of semiconductor package 50 may be marked with the one or more marks 52 according to mark information 26.

At step 208, visual inspection machine 30 may be used to facilitate inspection of surface 72 of semiconductor package 50. For example, visual inspection machine 30 may be used to inspect the one or more marks 52 on surface 72 of semiconductor package 50 for correctness, quality, adherence to printing pattern 18, compliance with marking information 26, or for any other suitable reason according to particular needs. In one embodiment, visual inspection machine 30 is operable to inspect surface 72 of semiconductor package 50 after marking equipment 16 has marked surface 72 of semiconductor package 50 with the one or more marks 52 according to printing pattern 18. In another embodiment, visual inspection machine 30 is operable to inspect surface 72 of semiconductor package 50 while marking equipment 16 is marking surface 72 of semiconductor package 50.

FIG. 5 illustrates an example method for determining highest wire loop position 74 within semiconductor package 50 using a predetermined threshold distance 77. Although the described method focuses on an example embodiment for determining highest wire loop position 74 within semiconductor package 50, the present invention contemplates determining the highest element position of any suitable semiconductor package 22 and of any suitable component within semiconductor package 22. At step 300, an expected marking depth of marking equipment 16 into surface 72 of semiconductor package 50 is determined. At step 302, a threshold distance 77 may be predetermined based on the expected marking depth, the predetermined threshold distance 77 being measured from surface 72 of semiconductor package 50 and forming imaginary threshold line 78. At step 304, portions of wire loops 68 within semiconductor package 50 that are closer to surface 72 of semiconductor package 50 than the predetermined threshold distance 77 (i.e., that are above threshold line 78) may be determined to be highest wire loop positions 74. At step 306, excluded surface portions 88 of surface 72 may be determined that correspond to highest wire loop positions 74 and any appropriate margins 84 and 86.

Although the present invention has been described with several embodiments, diverse changes, substitutions, variations, alterations, and modifications may be suggested to one skilled in the art, and it is intended that the invention encompass all such changes, substitutions, variations, alterations, and modifications as fall within the spirit and scope of the appended claims.

1. A method for marking a surface of a semiconductor package, comprising:
determining a highest element position within the semiconductor package;
determining an excluded surface portion of a surface of the semiconductor package corresponding to the highest element position;
determining a printing pattern for marking the surface of the semiconductor package with one or more marks, the printing pattern excluding the excluded surface portion of the surface of the semiconductor package; and
marking the surface of the semiconductor package with the one or more marks according to the determined printing pattern.

2. The method of claim 1, wherein the highest element position comprises a highest wire loop position.

3. The method of claim 2, wherein determining the highest wire loop position comprises:
identifying a critical area formed between a first element and one or more second elements of the semiconductor package;
determining the highest wire loop position to include the critical area.

4. The method of claim 3, wherein:
the first element comprises a bonding pad; and
the one or more second elements each comprise a lead of the semiconductor package.

5. The method of claim 1, wherein determining the highest element position comprises:
determining an expected marking depth of the one or more marks into the surface of the semiconductor package;
determining a predetermined threshold depth based on the expected marking depth, the predetermined threshold depth being measured from the surface of the semiconductor package; and
determining portions of elements within the semiconductor package that are closer to the surface of the semiconductor package than the predetermined threshold depth to be highest element positions.

6. The method of claim 1, further comprising:
determining a first margin from the highest element position;
determining a second margin from the highest element position; and
determining the excluded surface portion according to the determined first margin and the determined second margin.

7. The method of claim 1, further comprising configuring marking equipment used for marking the surface of the semiconductor package with the one or more marks according to the determined printing pattern.

8. The method of claim 7, wherein the marking equipment comprises laser marking equipment.

9. The method of claim 8, further comprising:
using a visual inspection machine to inspect the surface of the semiconductor package while marking the surface of the surface of the semiconductor package; and
if, using the visual inspection machine, the marking of the surface of the semiconductor package is determined to be undesirable, modifying the marking of the surface of the semiconductor package in response thereto.

10. A system for marking a surface of a semiconductor package, comprising:
a memory operable to store a highest element position within the semiconductor package;
one or more processors collectively operable to:
determine the highest element position within the semiconductor package;
determine an excluded surface portion of a surface of the semiconductor package corresponding to the highest element position; and
determine a printing pattern for marking the surface of the semiconductor package with the one or more marks, the printing pattern excluding the excluded surface portion of the surface of the semiconductor package; and
marking equipment operable to mark the surface of the semiconductor package with the one or more marks according to the determined printing pattern.

11. The system of claim 10, wherein the highest element position comprises a highest wire loop position.

12. The system of claim 11, wherein the highest wire loop position is determined by:
identifying a critical area formed between a first element and one or more second elements of the semiconductor package;
determining the highest wire loop position in the critical area.

13. The system of claim 12, wherein:
the first element comprises a bonding pad; and
the one or more second elements each comprise a lead of the semiconductor package.

14. The method of claim 10, wherein the highest element position is determined by:
determining an expected marking depth into the surface of the semiconductor package of the one or more marks;
determining a predetermined threshold depth based on the expected marking depth, the predetermined threshold depth being measured from the surface of the semiconductor package; and
determining portions of elements within the semiconductor package that are closer to the surface of the semiconductor package than the predetermined threshold depth to be highest element positions.

15. The system of claim 10, wherein the one or more processors are further collectively operable to:
determine a first margin from the highest element position;
determine a second margin from the highest element position; and
determine the excluded surface portion according to the determined first margin and the determined second margin.

16. The system of claim 10, wherein the one or more processors are further collectively operable to configure the marking equipment used to mark the surface of the semiconductor package with the one or more marks according to the determined printing pattern.

17. The system of claim 16, wherein the marking equipment comprises laser marking equipment.

18. The system of claim 10, further comprising a visual inspection machine operable to facilitate inspection of the surface of the semiconductor package while the marking equipment marks the surface of the semiconductor package with the one or more marks such that if the marking of the semiconductor package is determined to be undesirable, the marking of the semiconductor package can be modified.

19. A semiconductor package, comprising:
a first semiconductor element;
a second semiconductor element;
a wire loop coupling the first semiconductor element to the second semiconductor element, the wire loop comprising a highest wire loop position;
an excluded surface portion of a surface of the semiconductor package that corresponds to the highest wire loop position; and
one or more marks on the surface of the semiconductor package, the one or more marks printed according to a printing pattern that excludes the excluded surface portion of the surface of the semiconductor package.

20. The package of claim 19, further comprising:
a bonding pad area of the semiconductor package; and
a lead finger area of the semiconductor package;
a critical area formed between the bonding pad area and the lead finger area, the highest wire loop position being in the critical area.
